(19) United States
(12) Patent Application Publication
(10) Pub. No.: US 2008/0186650 A1
(43) Pub. Date: Aug. 7, 2008

(54) Decoupling Capacitor with Controlled Equivalent Series Resistance

(76) Inventors: Benjamin Beker, Spicewood, TX (US); Eric Tosaya, Fremont, CA (US)

Correspondence Address: TIMOTHY M HONEYCUTT ATTORNEY AT LAW, P O BOX 1577, CYPRESS, TX, 77410, US

(21) Appl. No.: 11/670,970

(22) Filed: Feb. 3, 2007

(51) Int. Cl. H01G 4/228; H05K 3/32

(52) U.S. Cl. 361/306.2; 29/832

(57) ABSTRACT

Decoupling capacitors and methods of manufacturing the same are provided. In one aspect, a method of manufacturing is provided that includes providing a semiconductor chip and providing a capacitor stack for the semiconductor chip. The capacitor stack includes a first group of terminations and a second group of terminations. A first group of electrodes is included that have terminals coupled to the first group of terminations and a second group of electrodes is included that have terminals coupled to the second group of terminations. At least one electrode of the first group of electrodes has at least one less terminal than the number of terminations in the first group of terminations in order to provide the capacitor stack with a known equivalent series resistance. The capacitor stack is electrically coupled to the semiconductor chip.

### BACKGROUND OF THE INVENTION

1. Field of the Invention

This invention relates generally to semiconductor processing, and more particularly to capacitive decoupling systems for integrated circuits and to methods of making the same.

2. Description of the Related Art

All integrated circuits require electrical power to operate, and packaged integrated circuits are no exception. Power is normally delivered to integrated circuits via a power supply and some form of power delivery network. Although currently-available power supplies are designed to supply stable voltages, the actual power delivered to integrated circuits can contain significant amounts of noise. There are many sources of noise, such as voltage fluctuations caused by other devices coupled to the power supply, electromagnetic interference and other causes.

Packaged integrated circuits use decoupling capacitors to lower noise on the power supply. Some of these decoupling capacitors are located off-chip. Conventional decoupling capacitors have a controlled capacitance, a constant intrinsic equivalent series inductance (ESL), and an equivalent series resistance (ESR). The capacitance and ESL of a decoupling capacitor (or network of capacitors) are used to reduce the power delivery network impedance in a particular frequency range. The frequency range of interest is often about 10 to 50 MHZ. The ESR of a capacitor determines the amount by which the power delivery network impedance is reduced and the frequency range where this occurs. In general, the lower the ESR, the more limited the frequency band in which the capacitor is effective in lowering impedance.

The ESR of a conventional capacitor is inversely proportional to the capacitance. However, ESR is not controlled in conventional systems. Consequently, where higher values of capacitance are desirable, the ESR may be undesirably low. It would be helpful to be able to use ESR as a controllable design parameter.

The present invention is directed to overcoming or reducing the effects of one or more of the foregoing disadvantages.

### SUMMARY OF THE INVENTION

In accordance with one aspect of the present invention, a method of manufacturing is provided that includes providing a semiconductor chip and providing a capacitor stack for the semiconductor chip. The capacitor stack includes a first group of terminations and a second group of terminations. A first group of electrodes is included that have terminals coupled to the first group of terminations and a second group of electrodes is included that have terminals coupled to the second group of terminations. At least one electrode of the first group of electrodes has at least one less terminal than the number of terminations in the first group of terminations in order to provide the capacitor stack with a known equivalent series resistance. The capacitor stack is electrically coupled to the semiconductor chip.

In accordance with another aspect of the present invention, a method of manufacturing is provided that includes providing a semiconductor chip, selecting an equivalent series resistance for a capacitor stack and providing a capacitor stack for the semiconductor chip. The capacitor stack includes a first group of terminations and a second group of terminations. A first group of electrodes is included that have terminals coupled to the first group of terminations and a second group of electrodes is included that have terminals coupled to the second group of terminations. At least one electrode of the first group of electrodes is provided with a sheet resistance requisite to provide the capacitor stack with the equivalent series resistance. The capacitor stack is electrically coupled to the semiconductor chip.

In accordance with another aspect of the present invention, an apparatus is provided that includes a semiconductor chip and a capacitor stack electrically coupled to the semiconductor chip. The capacitor stack includes a first group of terminations and a second group of terminations. A first group of electrodes is included that have terminals coupled to the first group of terminations and a second group of electrodes is included that have terminals coupled to the second group of terminations. At least one electrode of the first group of electrodes has at least one less terminal than the number of terminations in the first group of terminations in order to provide the capacitor stack with a known equivalent series resistance.

In accordance with another aspect of the present invention, an apparatus is provided that includes a semiconductor chip and a capacitor stack electrically coupled to the semiconductor chip. The capacitor stack includes a first group of terminations and a second group of terminations. A first group of electrodes is included that have terminals coupled to the first group of terminations and a second group of electrodes is included that have terminals coupled to the second group of terminations. At least one electrode of the first group of electrodes is provided with a sheet resistance requisite to provide the capacitor stack with a preselected equivalent series resistance.

### BRIEF DESCRIPTION OF THE DRAWINGS

The foregoing and other advantages of the invention will become apparent upon reading the following detailed description and upon reference to the drawings in which:

FIG. 1 is a pictorial view of an exemplary embodiment of a computer system;

FIG. 2 is an exploded pictorial view of a processor stack from the computer system depicted in FIG. 1;

FIG. 3 is a pictorial view of a conventional decoupling capacitor for the system depicted in FIG. 1;

FIG. 4 is a pictorial view of another type of conventional decoupling capacitor for the system depicted in FIG. 1;

FIG. 5 is an exploded pictorial of an exemplary embodiment of a decoupling capacitor that may be used with the system of FIG. 1;

FIG. 6 is a plan view of an electrode of the exemplary embodiment of a decoupling capacitor depicted in FIG. 5;

FIG. 7 is an exploded pictorial of an alternate exemplary embodiment of a decoupling capacitor;

FIG. 8 is a pictorial view of an exemplary process step to fabricate components of a decoupling capacitor; and

FIG. 9 is a pictorial view of another exemplary process step to fabricate components of a decoupling capacitor.

### DETAILED DESCRIPTION OF SPECIFIC EMBODIMENTS

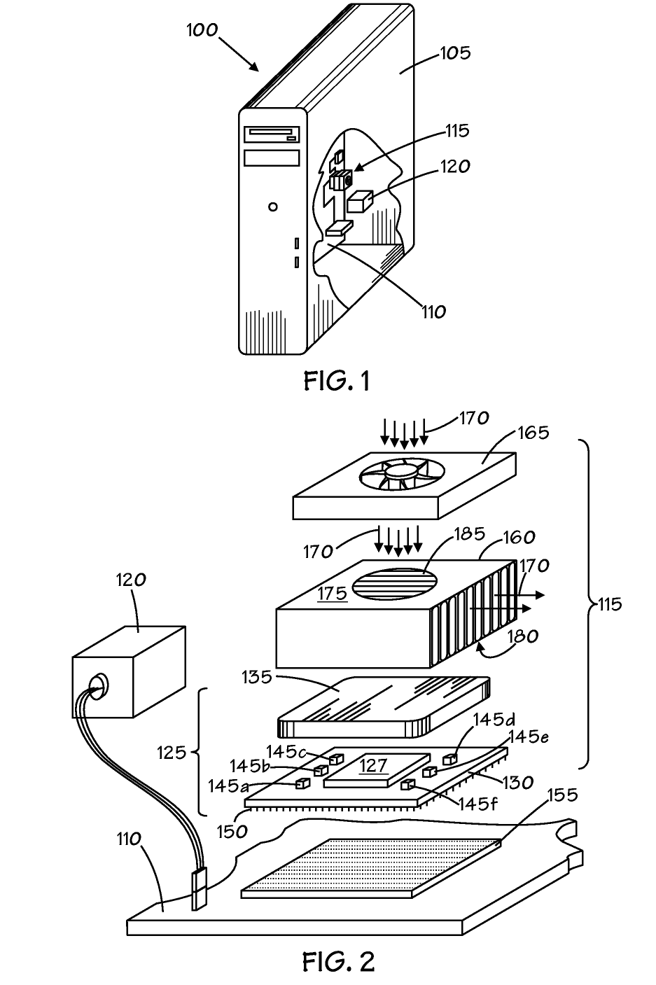

In the drawings described below, reference numerals are generally repeated where identical elements appear in more than one figure. Turning now to the drawings, and in particular to FIG. 1, therein is shown a pictorial view of an exemplary embodiment of a computer system 100 that includes an enclosure 105. A portion of the enclosure 105 is shown cut away to reveal various components of the computer system 100, including a printed circuit or mother board 110 and a processor stack 115. In addition, a power supply 120 is shown. The skilled artisan will appreciate that the computer system 100 might be a personal computer, a server, a part of a larger computer system, a device for testing integrated circuits or any of a huge myriad of other types of devices where integrated circuits are used.

Additional detail regarding the processor stack 115 depicted in FIG. 1 may be understood by referring now also to FIG. 2, which is an exploded pictorial that shows the processor stack 115 itself exploded, and also exploded from the underlying mother board 110. The motherboard 110 is of such size that only a portion thereof is depicted in FIG. 2. The processor stack 115 includes an integrated circuit package 125 for holding an integrated circuit 127. The package 125 has a base substrate 130 and an overlying lid 135. Optionally, the package 125 may be lidless, partially or completely overmolded, or glob topped. The substrate 130 may be a printed circuit board. The lid 135 may be composed of well-known plastics, ceramics or metallic materials as desired. Some exemplary materials include nickel plated copper, anodized aluminum, aluminum-silicon-carbon, aluminum nitride, boron nitride or the like. In an exemplary embodiment, the lid 135 is composed of nickel-coated copper. The integrated circuit 127 is mounted to the substrate 130. The integrated circuit 127 may be a semiconductor device or other type of device as desired. The integrated circuit 127 may be any of a myriad of different types of circuit devices used in electronics, such as, for example, microprocessors, application specific integrated circuits, memory devices or the like. The substrate 130 may be composed of well-known plastics, ceramics, or other materials commonly used for integrated circuit packaging.

One or more decoupling capacitors 145a, 145b, 145c, 145d, 145e and 145f are mounted on the substrate 130. Optionally, some or all of the capacitors 145a, 145b, 145c, 145d, 145e and 145f may be mounted on the lower side or even within the substrate 130. The capacitors 145a, 145b, 145c, 145d, 145e and 145f are designed to provide local decoupling for power delivered from the power supply 120 and/or other sources of power that may be provided to the integrated circuit 127. The substrate 130 is provided with a plurality of conductor pins 150 that are designed to seat in respective sockets in a socket 155 positioned on the printed circuit board 110. Power is delivered to the integrated circuit 127 through one or more of the pins 150. Connection methods other than pin-socket, such as soldering, land grid array, ball grid array, surface-mounted pin grid arrays or the like may be used to electrically interconnect the substrate 130 with the motherboard 110.

Cooling of the integrated circuit 127 is provided by way of a heat sink 160 that is designed to be positioned on the package 125 and an optional cooling fan 165 that is designed to be positioned on, slightly above or to the side of the heat sink 160, and provide a flow of air 170. The heat sink 160 may take on a myriad of different shapes and configurations and be composed of metallic or non-metallic materials as desired. Metallic materials, such as copper and alloys thereof, tend to have relatively advantageous coefficients of conductive heat transfer. The heat sink 160 has a side 175 that is designed to face towards and/or be seated on the package 125 and a side 180 that is designed to face towards and/or support the fan 165. The heat sink 160 and the package 125 are adapted to be arranged in the stack 115 that normally includes the fan 165. The stack 115 is depicted in a relatively vertical orientation in FIG. 2. However, the skilled artisan will appreciate that the stack 115 may actually appear to be sideways or otherwise oriented in an actual enclosure, such as the enclosure 105 depicted in FIG. 1. The heat sink 160 may be provided with an opening 185 to allow the air 170 to flow through the side 175 and exit laterally and it should be understood that the flow direction of the air 170 may be reversed if desired. The skilled artisan will appreciate that the heat sink 160 is designed to convey heat away from the integrated circuit 127. Accordingly, it should be understood that this may be accomplished by air cooling, liquid cooling or a combination of the two.

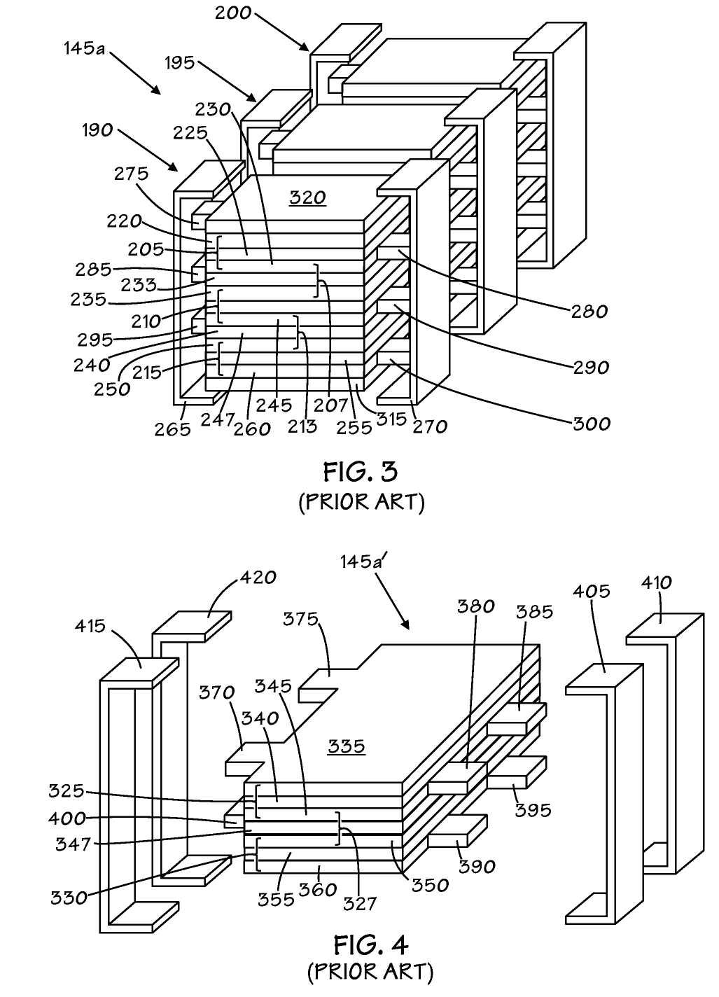

Additional detail regarding a conventional design for the decoupling capacitors 145a, 145b, 145c, 145d, 145e and 145f may be understood by referring now to FIG. 3, which is a pictorial view of the decoupling capacitor 145a and is illustrative of the structure and function of the other decoupling capacitors 145b, 145c, 145d, 145e and 145f. It should be understood that FIG. 3 is somewhat simplified for clarity of illustration in that an insulating material or other type of enclosure of the decoupling capacitor 145a is not shown. The decoupling capacitor 145a includes three capacitor stacks 190, 195 and 200. The following description of the structure and function of the stack 190 will be illustrative of the other stacks 195 and 200 as well. The stack 190 includes five capacitors 205, 207, 210, 213 and 215. The capacitor 205 consists of an upper electrode 220, a dielectric layer 225 and a lower electrode 230. The capacitor 207 consists of the electrode 230, a capacitor dielectric 233, and an electrode 235. The capacitor 210 consists of the electrode 235, a dielectric layer 240 and a lower electrode 245. The capacitor 213 consists of the electrode 245, a capacitor dielectric 247, and an electrode 250. Finally, the capacitor 215 consists of the electrode 250, a dielectric layer 255 and a lower electrode 260. A given capacitor, such as the capacitor 205, is electrically interconnected to a voltage source and ground by way of terminations 265 and 270. In order to establish the interconnections, the electrode 220 is provided with a terminal or tab 275 and the electrode 230 is provided with a similar tab 280. Tabs 285 and 290 and 295 and 300 are provided for the capacitors 210 and 215 as well. A pair of dielectric layers 315 and 320 may sandwich the capacitors 205, 207, 210, 213 and 215 vertically as shown.

Another type of conventional decoupling capacitor 145a′ is depicted partially exploded in FIG. 4. Three capacitors 325, 327 and 330 are illustrated. The capacitor 325 consists of an upper electrode 335, a dielectric layer 340 and a lower electrode 345. The capacitor 327 consists of the electrode 345, a capacitor dielectric 347 and an electrode 350. The capacitor 330 consists of the electrode 350, a dielectric layer 355 and a lower electrode 360. Top and bottom dielectric layers are not shown for simplicity of illustration. This configuration of capacitor employs the so called multi-terminal electrode. In this regard, a given electrode, such as the electrode 335, includes multiple tabs 370 and 375. Similarly, the electrode 345 includes tabs 380 and 385, the electrode 360 includes tabs 390 and 395, and the electrode 350 includes a tab 400 and another tab that is not visible. The tabs 380 and 390 are connected to a termination 405 and the tabs 385 and 395 are connected to a termination 410. The tabs 370 and 400 are connected to a termination 415 and the tab 375 and the other tab (not visible) of the electrode 350 are connected to a termination 420. Note that the terminations 405, 410, 415 and 420 are shown exploded from the capacitor 145a′ so that the tabs 380, 385, 390 and 395 are visible. The terminations 415 and 420 may be connected to a power source and the terminations 405 and 410 may be connected to ground or vice versa.

The equivalent series resistance (“ESR”) and capacitance of a capacitor are related according to the following equation:

$$ESR \approx \frac{K}{C} \qquad Equation 1$$

where K is a constant that is empirically determined for a given capacitor. As noted in the Background section hereof, while ESR is a useful parameter to modify the impedance of power delivery networks and the frequency range in which that modification may occur, control of ESR has remained elusive. The inverse relationship between ESR and capacitance shown by Equation 1 can translate into lower than desired ESR in situations where larger capacitances are needed.

One conventional method modifying the ESR of the capacitor 145a′ depicted in FIG. 4 involves the complete elimination or open circuiting of one of the terminations 405, 410, 415 or 420. The effect of the removal of an entire termination does provide an increase in the ESR of the capacitor 145a′, albeit at the expense of a fairly radical departure from the original architecture of the capacitor 145a′ depicted in FIG. 4 and an attendant increase in equivalent series inductance. Furthermore, the removal of an entire termination can produce a somewhat more crude increase in ESR than is either needed or desired.

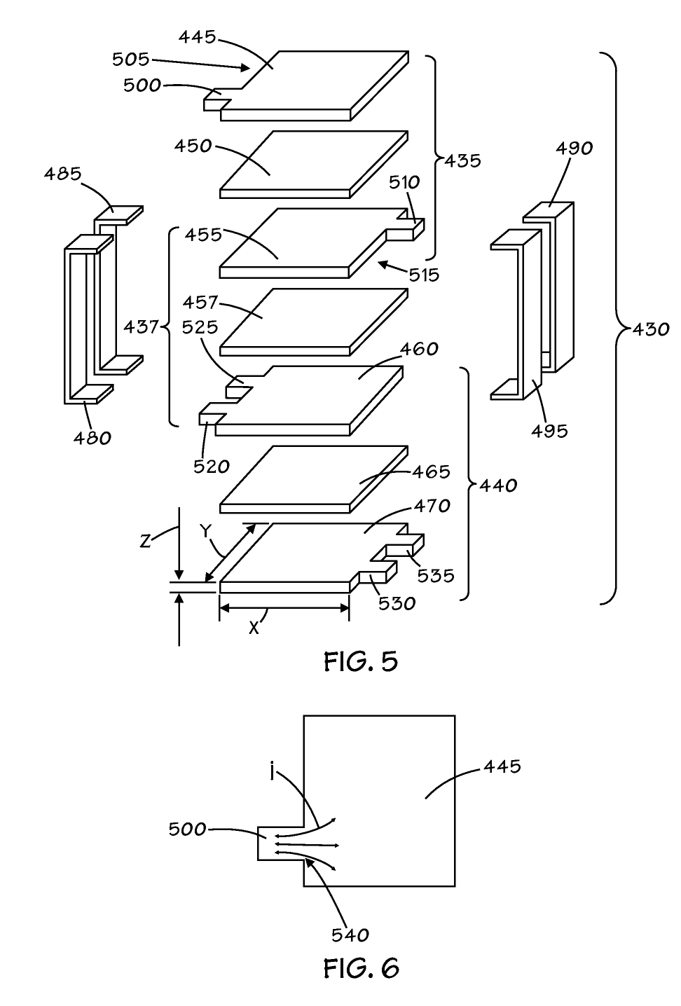

FIG. 5 is an exploded pictorial view of an exemplary embodiment of a decoupling capacitor 430 in accordance with aspects of the present invention. The capacitor 430 may be used with the semiconductor chip 127, the printed circuit board 130 and the printed circuit board 110 or other types of circuits and systems that benefit from capacitive decoupling. The capacitor 430 consists of a stack of parallel-connected capacitors 435, 437 and 440. Only three capacitors 435, 437 and 440 are shown for simplicity of illustration. However, the skilled artisan will appreciate that there may be many hundreds or more capacitors in the stack. Furthermore, many capacitors like the capacitor 430 may be used for the semiconductor chip 127 shown in FIG. 2. The capacitor 435 consists of a single-terminal electrode 445, a capacitor dielectric layer 450 and another single-terminal electrode 455. The capacitor 437 consists of the single-terminal electrode 455, a capacitor dielectric layer 457, and a two-terminal electrode 460. Finally, the capacitor 440 consists of the two-terminal electrode 460, a capacitor dielectric 465 and a two-terminal electrode 470.

A first group of two terminations 480 and 485 are connected to one side of the capacitors 435, 437 and 440 and a second group of two terminations 490 and 495 are connected to the other side of the capacitors 435, 437 and 440. The first group of terminations 480 and 485 are coupled to the group of electrodes consisting of the electrodes 445 and 460. The second group of terminations 490 and 495 are coupled to the group of electrodes consisting of the electrodes 455 and 470. The first group of terminations 480 and 485 are biased at some level, which may be ground, and the second group of terminations 490 and 495 are usually biased at the opposite level, which may be ground.

Unlike the conventional capacitor design depicted in FIG. 4, the capacitor 430 is fabricated in such a way that a given electrode in a group of electrodes, such as the electrode 445 in the group of electrodes 445 and 460, is fabricated with at least one terminal less than the number of available terminations in a group, such as the group of terminations 480 and 485. Assume for the purposes of illustration that the two terminations 480 and 485 are biased to some voltage level V with respect to ground and the two terminations 490 and 495 are grounded. The electrode 445 is provided with a single tab 500 when there are two terminations 480 and 485 available. A terminal which might otherwise be positioned at the location designated 505 and be connected to the termination 485 is eliminated. The elimination of the terminal in the location 505 for the electrode 445 while the tab 500 is maintained in connection with the termination 480 has the effect of increasing the ESR of the capacitor 435, and thus the capacitor 430, without negatively impacting the capacitances thereof. Similarly, the electrode 455 is provided with a single tab 510 when there are two terminations 490 and 495 available for connection. A tab which might otherwise be positioned at the location designated 515 and be connected to the termination 495 is eliminated. The middle capacitor 437 consisting of the single-tab electrode 455 and the double-tab electrode 460 also exhibits a higher ESR than a completely multi-tab electrode configuration with all tabs connected to available terminations.

The lower capacitor 440 may be configured as a typical multi-terminal capacitor. The electrode 460 may be provided with two tabs 520 and 525 for respective connection to the terminations 480 and 485 and the electrode 470 may be provided with two tabs 530 and 535 for respective connection to the terminations 490 and 495. Note that a given electrode, such as the electrode 470 has an X dimension, a Y dimension and a thickness Z.

The arrangement in FIG. 5 illustrates just one possible scenario. While the electrodes 460 and 470 may be provided with multiple tabs, one or both of them could be provided with a single tab as desired. Furthermore, there may be tabs positioned anywhere about the periphery of a given or all of the electrodes. Designs with lower inductance can use terminations on more than just two sides of a given electrode. The benefits of controllable increased ESR are achieved where there are N terminations 480, 485 etc. and at least one electrode with N-1 tabs.

Computer simulations using SPICE were performed to determine the relationship between electrode configuration and ESR. In the first simulation, a capacitor modeled after a stack consisting of the capacitors 325, 327 and 330 positioned on top of another stack consisting of three more of the capacitors 325, 327 and 330 depicted in FIG. 4 connected in parallel and coupled to four terminations 405, 410, 415 and 420 was evaluated for ESR, equivalent series inductance and total capacitance. It should be noted that the stack of two sets of three actually yielded seven total capacitors in the simulated conventional stack. The simulation was based on copper electrodes with an X dimension (see FIG. 5 for example dimensions) of 2.2 mm, a Y dimension of 8.5 mm, a Z dimension of 0.01 mm and a capacitor dielectric thickness, i.e. the thickness of, for example, the dielectric layer 465 in FIG. 5, of 0.16 mm. In addition, the simulation assumed that the air served as the capacitor dielectrics.

To examine the response of ESR to the elimination of one or more tabs in the electrodes, a second simulation was performed. In the second simulation, a capacitor modeled after a stack consisting of the capacitors 435, 437 and 440 positioned on top of another stack consisting of three more of the capacitors 435, 437 and 440 all connected in parallel and arranged with the four terminations 480, 485, 490 and 495 was evaluated for ESR, ESL and total capacitance. It should be noted that the stack of two sets of three capacitors actually yielded seven total capacitors in the simulated stack. The second simulation was based on the same electrode and capacitor dielectric dimensions and materials as the first simulation. The first and second simulations yielded the following data:

| | Total | Equivalent | Equivalent Series |
|---|---|---|---|
| | Capacitance | Series Resistance | Inductance |
| Simulation | (pF) | (mΩ) | (nH) |
| 1st Simulation | 4.0 | 5.82 | 0.753 |
| Modeled on | | | |
| Conventional | | | |
| Capacitor | | | |
| Stack | | | |
| 2nd | 4.0 | 8.33 | 0.826 |
| Simulation | | | |
| Modeled on | | | |
| New Capacitor | | | |
| Stack | | | |

A few observations may be made at this point. The elimination of tabs did not decrease the total capacitance. This result is to be expected since at least one terminal or tab for each electrode remains connected to a termination. The ESR increased from 5.82 mΩ to 8.33 mΩ: a 43% increase. The equivalent series inductance increased from 0.753 nH to 0.826 nH: a 9.7% increase. The increase in equivalent series inductance, while not altogether desirable, is nevertheless relatively modest, particularly in view of the favorably steep increase in ESR. The simulation establishes and the skilled artisan will appreciate that the limitations of Equation 1 above can be overcome. It should be noted that this change in equivalent series inductance will be less prominent when the number of electrodes becomes large. At that point, it is anticipated that the increase in equivalent series inductance will become negligible. In situations where larger capacitances are needed, the tab configurations of the electrodes in a capacitor can be modified to prevent the ESR of the capacitor from plummeting when the capacitor is provided with greater capacitance.

The same modeling technique may be used to generate data tables that are predictive of the ESR yielded by a variety of capacitor configurations. Such a data table may take on a variety of forms, one of which may be as follows for some exemplary capacitor configurations a, b, c . . . x:

Data Table

| | | | Equivalent | Equivalent |
|---|---|---|---|---|
| Total | | Total | Series | Series |
| Capacitors | | Capacitance | Resistance | Inductance |
| in Stack | Configuration | (pF) | (mΩ) | (nH) |
| 500 | a capacitor with | Cₐ | Rₐ | Lₐ |
| | number of tabs T = | | | |
| | number of | | | |
| | terminations N | | | |
| | alternating with a | | | |
| | capacitor with number | | | |
| | of tabs T = N − 1 | | | |
| 250 | a capacitor with | C_{b} | Rₐ | L_{b} |
| | number of tabs T = | | | |
| | number of | | | |
| | terminations N | | | |
| | alternating with a | | | |
| | capacitor with number | | | |
| | of tabs T = N − 2 | | | |
| 750 | two capacitors with | C_{c} | Rₐ | L_{b} |
| | number of tabs T = | | | |
| | number of | | | |
| | terminations N | | | |
| | alternating with a | | | |
| | capacitor with number | | | |
| | of tabs T = N − 1 | | | |
| . | . | . | . | . |
| . | . | . | . | . |
| . | . | . | . | . |
| X | M capacitor(s) with | Cₓ | Rₓ | Lₓ |
| | number of tabs T = or | | | |
| | ≠ number of | | | |
| | terminations N | | | |
| | alternating with a | | | |
| | capacitor with number | | | |
| | of tabs T = N − K | | | |

Attention is now turned to FIG. 6, which is a top view of the electrode 445 of the capacitor 435 shown in FIG. 5. It is anticipated that while the provision of the single tab 530 for the electrode 445 will not diminish the capacitance of the capacitor 435 of which the electrode 445 is a component, the single tab configuration will nevertheless provide what is in essence a bottleneck for current I passing through the region numbered 540 on the electrode 445. The bottleneck at 540 will result in an increased ESR for the capacitor 435 and the stack 430 depicted in FIG. 5.

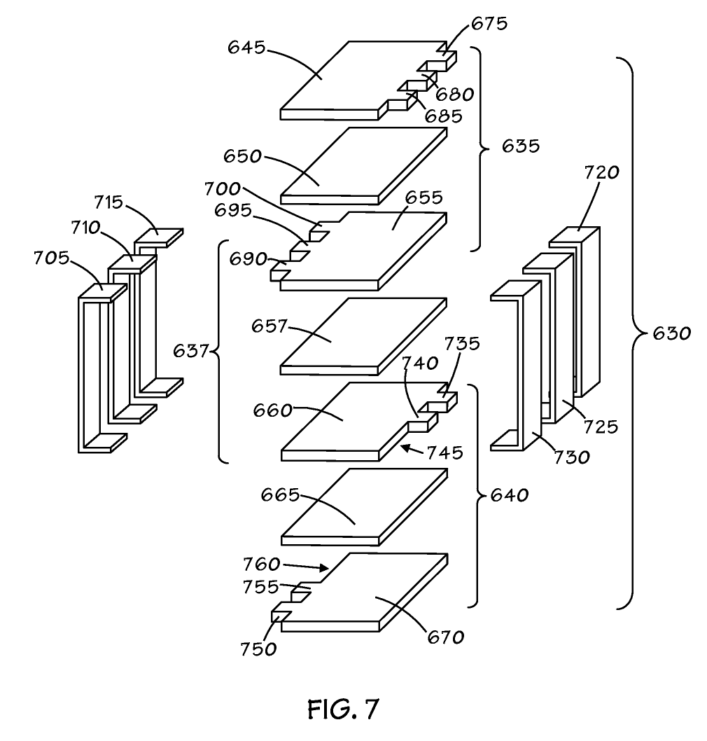

An alternate exemplary embodiment of a decoupling capacitor is depicted in FIG. 7, which is an exploded pictorial. In this illustrative embodiment, a capacitor 630 includes three parallel-connected stacked capacitors 635, 637 and 640. The capacitor 635 consists of an electrode 645, a dielectric layer 650, and an electrode 655. The capacitor 637 consists of the electrode 655, a dielectric layer 657 and an electrode 660. The capacitor 640 consists of the electrode 660, a dielectric layer 665 and an electrode 670. The electrodes 645 and 655 of the capacitor 635 are provided with respective multiple tabs 675, 680, 685, 690, 695 and 700 to accommodate the three terminations on each of the electrodes 645 and 655. A first group of three terminations 705, 710 and 715 are provided to connect to the tabs 690, 695 and 700 and another group of three terminations 720, 725 and 730 are provided to connect to the tabs 675, 680 and 685 of the electrode 645. Thus, the upper and lower electrodes 645 and 655 are provided with a number of terminals to match the number of terminations. However, the capacitors 637 and 640 are fabricated in such a way as to modify the ESR thereof and thus of the overall capacitor 630. In this regard, the upper electrode 660 is provided with two tabs 735 and 740, that is, one less tab than the number of terminations in the group of terminations 720, 725 and 730 available. The space 745 where a third tab would ordinarily appear is not provided with a tab and thus no connection is made to the termination 730. The electrode 670 is similarly provided with two tabs 750 and 755 but no tab in the space 760. In this way, connections are made between the tabs 750 and 755 and the terminations 705 and 710 but no connection is made to the terminations 715. In this manner, the ESR of the capacitors 637 and 640 are increased without affecting the individual capacitances thereof through the imposition of current bottle necking in the tabs 735, 740, 750 and 755 of the electrodes 660 and 670 as generally described above in conjunction with FIG. 5. Here again, at least one electrode 660 of the group of electrodes 645 and 660 has at least one terminal less than the number of terminations in the corresponding group of terminations 720, 725 and 730.

Again, it should be understood that the following parameters are variable: (1) the number of tabs provided for a given electrode: (2) the number of individual capacitors in a given capacitor stack; and (3) the number of total capacitors connected in parallel. Furthermore, it should be understood that the illustrated configuration of the various terminations in the foregoing embodiments as C-shaped structures is also subject to design discretion. Other types of termination structures may be used as desired.

A variety of techniques may be used to manufacture the capacitors disclosed herein. Screen printing and stencil printing represent two examples. In one exemplary embodiment, a screen printing process is used. Attention is now turned to FIG. 8, which is a simplified pictorial view of a template 800 that may be used in conjunction with a wire mesh screen 805 to print a metal electrode on an underlying dielectric film 810. The template 800 is typically formed from a ceramic slurry that is cast on the mesh screen 805 and allowed to dry. The template 800 is provided with a patterned opening 815 that has the desired shape for the electrode to be printed. In this illustration, it is assumed that the template 800 is shaped appropriately to print the electrode 670 depicted in FIG. 7. There may be multiple templates 800 on a given screen 805. The dielectric film 810 is advantageously formed from high dielectric constant or so-called “high K” ferroelectric materials suitable to serve as the capacitor dielectric layers disclosed elsewhere herein. Exemplary materials include, for example, barium titanate, strontium titanate, magnesium titanate, barium neodymium titanate, barium strontium titanate, calcium magnesium titanate, tantalum oxide, titanate, zirconium tin titanate or the like. Additives, such as alumina, magnesia, berylia, calcium, corderite (Mg+Al+SiO2), forsterite, niobate, silica, zirconia, boro-silicate or the like may be used to modify the high temperature and dielectric constant properties of the dielectric layer 810. The dielectric layer 810 may be in the form of a sheet or a tape. Commercially available examples are known in the industry as “green sheets” or “green tapes.”

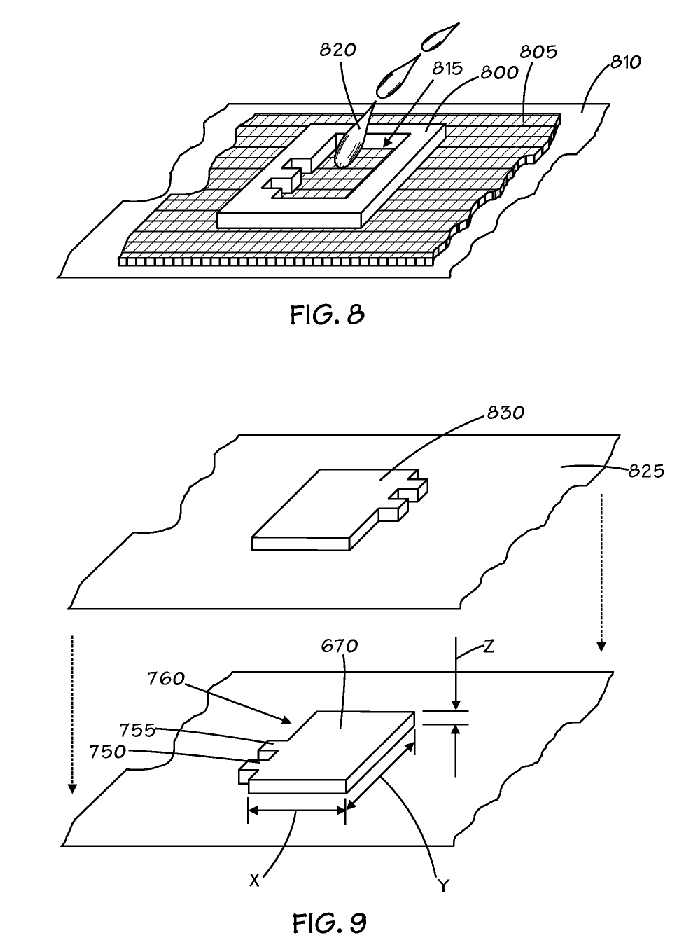

After the mesh 805 and the template 800 are positioned over the dielectric sheet/tape 810, a suitable conducting material 820 is deposited in the opening 815 and forced by way of pressure through the mesh 805 to form an electrode in the shape of the opening 815 on the dielectric sheet/tape 810. The conducting material 820 may be composed of a variety of materials. In an exemplary embodiment, a copper powder is mixed with various ceramic powders, such as silica or boron oxide or both and a solvent. Silver, gold, palladium, platinum, gold-tin alloy, nickel, tantalum nitride, titanium-tungsten, mixtures of these or the like may optionally be used as the base conductor. The ceramics aid in wetting to the dielectric layer 810. When the mesh 805 and the template 800 are removed, the electrode 670 remains on the dielectric tape 810 as shown in FIG. 9. FIG. 9 is a pictorial view of the electrode 670 positioned on the dielectric tape 810. The process may be repeated numerous times and the resulting electrode 670 and dialect tape 810 may be stacked on another dielectric tape 825 and electrode 830. Large numbers of such electrodes may be stacked up to form a given capacitor, such as the capacitor 630 shown in FIG. 7. The printing of the electrode 670 with two tabs 750 and 755 but without a tab at the location 760 is done by selecting an appropriately-shaped template 800. After stacking, a furnace process is used to bake the stack of electrodes 670 and 830 and dielectrics 810 and 825 into a fused stack. If desired, the tabs 750 and 755 and the two other tabs not numbered may be coated with nickel and tin to facilitate later soldering of terminations and restrict copper diffusion.

The tailoring of the composition of the electrode 670 may be used as another way to control the ESR of the electrode 670, and thus the ESR of a capacitor incorporating the electrode 670. The sheet resistance is a direct measure of the ESR of the electrode 670. The sheet resistance of the electrode 670 may be determined using the dimensions, particularly the thickness Z, and the bulk resistivity of the electrode 670. The X, Y and Z dimensions of the electrode 670 are known as well as the corresponding dimensions of the tabs 750 and 755. The thickness Z of the electrode 670 after baking is the most useful dimension. The bulk resistivity is dependent on the composition of the conducting material 820 (see FIG. 8). Copper has a relatively low bulk resistivity. If an ESR higher than that provided by copper is desired, the copper may be diluted or substituted with another material or materials. For example, tungsten may be chosen instead of copper as a base conductor. In another example, copper may be diluted with molybdenum alone or with tungsten. With a known bulk resistivity and thickness Z in hand, the ESR may be computed.

The skilled artisan will appreciate the ESR of a capacitor may be controlled by a combination of the two techniques disclosed herein. Thus, the selective elimination of tabs for certain electrodes and the selection of a particular composition of the electrode material may be used in tandem to achieve a desired ESR.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

1. A method of manufacturing, comprising:
providing a semiconductor chip;
providing a capacitor stack for the semiconductor chip, the capacitor stack including a first group of terminations and a second group of terminations, a first group of electrodes having terminals coupled to the first group of terminations and a second group of electrodes having terminals coupled to the second group of terminations, at least one electrode of the first group of electrodes having at least one less terminal than, and at least one electrode of the first group of electrodes having a number of terminals at least as great as, the number of terminations in the first group of terminations in order to provide the capacitor stack with a known equivalent series resistance; and electrically coupling the capacitor stack to the semiconductor chip.

2. The method of claim 1, comprising coupling the semiconductor chip to a first printed circuit board.

3. The method of claim 2, comprising coupling the first printed circuit board to a second printed circuit board.

4. The method of claim 1, wherein the first group of terminations and the second group of terminations each comprise two terminations.

5. The method of claim 1, wherein at least one electrode of the second group of electrodes has at least one less terminal than the number of terminations in the second group of terminations.

6. The method of claim 1, comprising selecting an equivalent series resistance for the capacitor stack and providing at least one electrode of the first group of electrodes with a sheet resistance requisite to provide the capacitor stack with the known equivalent series resistance.

7. A method of manufacturing, comprising:
providing a semiconductor chip;
selecting an equivalent series resistance for a capacitor stack;
providing a capacitor stack for the semiconductor chip, the capacitor stack including a first group of terminations and a second group of terminations, a first group of electrodes having terminals coupled to the first group of terminations and a second group of electrodes having terminals coupled to the second group of terminations;
determining a sheet resistance for at least one electrode of the first group of electrodes sufficient to provide the selected equivalent series resistance for the capacitor stack;
providing the at least one electrode of the first group of electrodes with the sheet resistance sufficient to provide the capacitor stack with the selected equivalent series resistance; and
electrically coupling the capacitor stack to the semiconductor chip.

8. The method of claim 7, comprising coupling the semiconductor chip to a first printed circuit board.

9. The method of claim 8, comprising coupling the first printed circuit board to a second printed circuit board.

10. The method of claim 7, wherein the first group of terminations and the second group of terminations each comprise two terminations.

11. The method of claim 7, wherein the step of providing the at least one electrode of the first group of electrodes with a sheet resistance requisite to provide the capacitor stack with the equivalent series resistance comprises forming the at least one electrode with selected dimensions and from a combination of materials having a known bulk resistivity.

12. An apparatus, comprising:
a semiconductor chip;
a capacitor stack electrically coupled to the semiconductor chip, the capacitor stack including a first group of terminations and a second group of terminations, a first group of electrodes having terminals coupled to the first group of terminations and a second group of electrodes having terminals coupled to the second group of terminations, at least one electrode of the first group of electrodes having at least one less terminal than, and at least one electrode of the first group of electrodes having a number of terminals at least as great as, the number of terminations in the first group of terminations in order to provide the capacitor stack with a known equivalent series resistance.

13. The apparatus of claim 12, comprising a first printed circuit board coupled to the semiconductor chip.

14. The apparatus of claim 13, comprising a second printed circuit board coupled to the first printed circuit board.

15. The apparatus of claim 12, wherein the first group of terminations and the second group of terminations each comprise two terminations.

16. The apparatus of claim 12, wherein at least one electrode of the second group of electrodes has at least one less terminal than the number of terminations in the second group of terminations.

17-22. (canceled)
